(19) United States
(12) Patent Application Publication
(10) Pub. No.: US 2010/0012179 A1
(43) Pub. Date: Jan. 21, 2010

(54) SOLAR CELL WITH HIGH PHOTON UTILIZATION AND METHOD OF MANUFACTURING THE SAME

(76) Inventor: Chien-Li Cheng, Hsinchu City (TW)

Correspondence Address: Muncy, Geissler, Olds & Lowe, PLLC, P.O. BOX 1364, FAIRFAX, VA, 22038-1364, US

(21) Appl. No.: 12/372,975

(22) Filed: Feb. 18, 2009

(30) Foreign Application Priority Data
Jul. 17, 2008 (TW) 097127067

(51) Int. Cl. H01L 31/00; H01L 21/3105; H01L 21/02

(52) U.S. Cl. 136/256; 438/71; 438/72; 257/E21.215; 257/E21.002

(57) ABSTRACT

A solar cell with high photon utilization includes a substrate, a transparent conductive oxide layer, an anti-reflection coating (ARC) layer and at least one main charge collecting line. The substrate has a front side and a back side. The substrate has a first-type semiconductor layer close to the back side and a second-type semiconductor layer close to the front side. The transparent conductive oxide layer is formed on the front side. The ARC layer is formed on the transparent conductive oxide layer. The main charge collecting line penetrates through the ARC layer and projects from the ARC layer, and the main charge collecting line is electrically connected to the transparent conductive oxide layer. A method of manufacturing the solar cell is also disclosed.

This application claims priority of No. 097127067 filed in Taiwan R.O.C. on Jul. 17, 2008 under 35 USC 119, the entire content of which is hereby incorporated by reference.

### BACKGROUND OF THE INVENTION

1. Field of Invention

The invention relates to a solar cell with high photon utilization and a method of manufacturing the same, and more particularly to a solar cell having a transparent conductive oxide layer and a method of manufacturing the same.

2. Related Art

FIG. 1 is a top view showing a conventional solar cell. Referring to FIG. 1, the conventional solar cell includes a silicon substrate 110, an ARC layer 120 and two main charge collecting lines 150 and a plurality of secondary charge collecting lines 160 disposed on the ARC layer 120. The ARC layer 120 is usually made of silicon nitride and has the thickness of about 800 angstroms.

However, the anti-reflective effect of the ARC layer 120 is still restricted, and the ARC layer 120 must have a predetermined thickness and the ARC layer 120 may reduce the conductive effect. So, the density of the secondary charge collecting lines 160 of the conventional solar cell is higher, and the area of the light input surface is thus reduced. Consequently, the photon utilization of the conventional solar cell cannot be effectively enhanced.

Thus, it is an important issue of this invention to provide a solar cell with high photon utilization and a method of manufacturing the same.

### SUMMARY OF THE INVENTION

It is therefore an object of the invention to provide a solar cell with high photon utilization and a method of manufacturing the same, wherein a transparent conductive oxide layer is utilized to enhance the photon utilization of the solar cell.

The invention achieves the above-identified object by providing a solar cell with high photon utilization. The solar cell includes a substrate, a transparent conductive oxide layer, an anti-reflection coating (ARC) layer and at least one main charge collecting line. The substrate has a front side and a back side. The substrate has a first-type semiconductor layer close to the back side and a second-type semiconductor layer close to the front side. The transparent conductive oxide layer is formed on the front side. The ARC layer is formed on the transparent conductive oxide layer. The main charge collecting line penetrates through the ARC layer and projects from the ARC layer, and is electrically connected to the transparent conductive oxide layer.

The invention also provides a method of manufacturing a solar cell. The method includes the steps: providing a substrate having a front side and a back side; doping the substrate such that the substrate has a first-type semiconductor layer close to the back side and a second-type semiconductor layer close to the front side; forming a transparent conductive oxide layer on the front side of the substrate; forming an anti-reflection coating (ARC) layer on the transparent conductive oxide layer; forming at least one main charge collecting line on the ARC layer; and firing at least one main charge collecting line such that at least one main charge collecting line penetrates through the ARC layer and is electrically connected to the transparent conductive oxide layer.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a top view showing a conventional solar cell.

FIG. 2 is a top view showing a solar cell according to a preferred embodiment of the invention.

FIG. 3 is a cross-sectional view showing the solar cell taken along a line 3-3 of FIG. 2.

FIG. 4 is a flow chart showing a method of manufacturing the solar cell according to the invention.

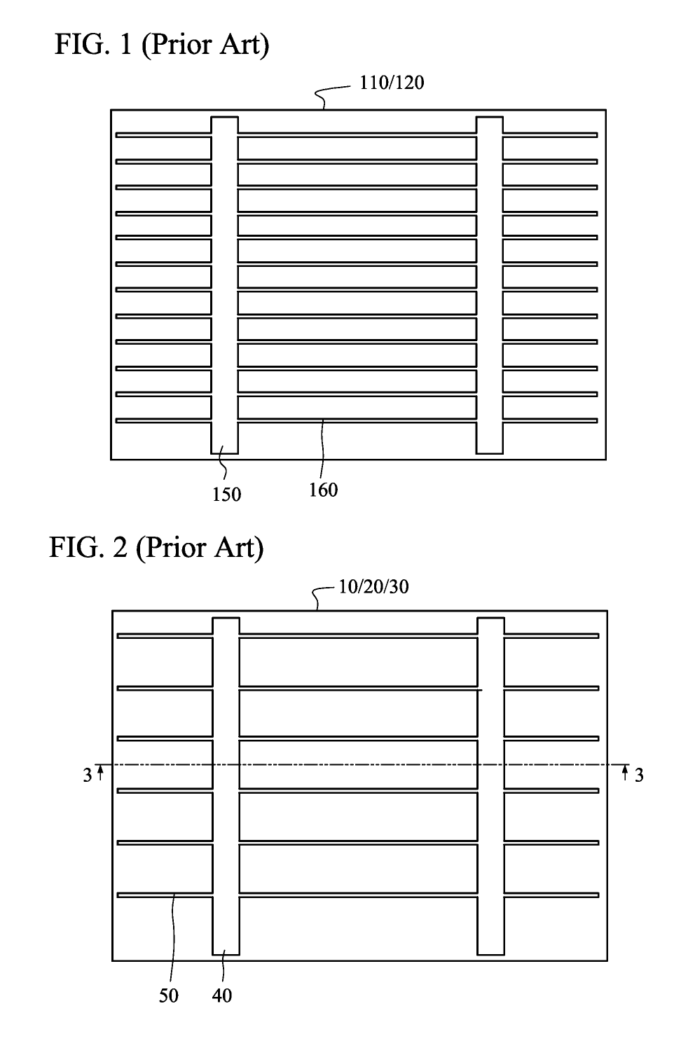

### DETAILED DESCRIPTION OF THE INVENTION

The present invention will be apparent from the following detailed description, which proceeds with reference to the accompanying drawings, wherein the same references relate to the same elements.

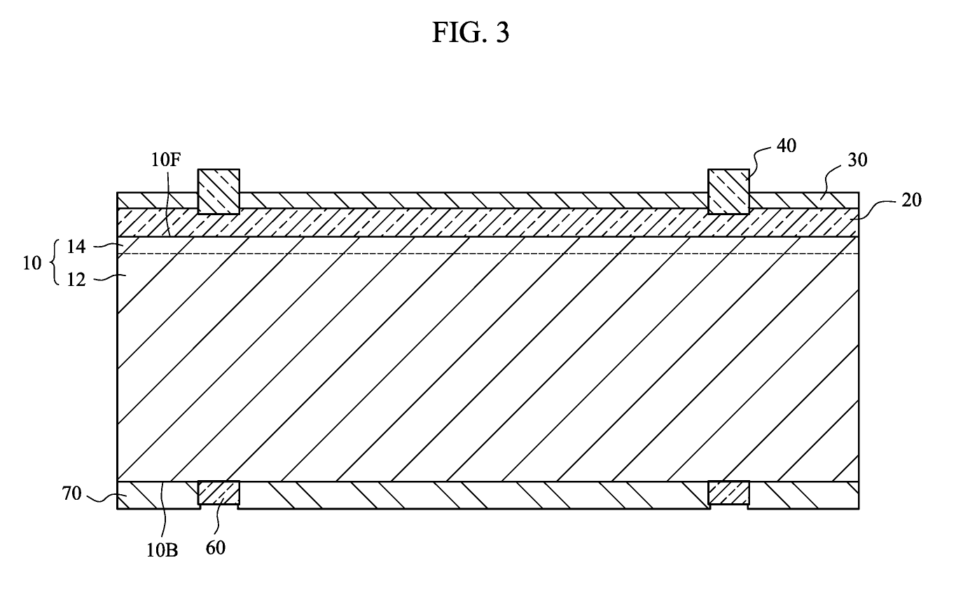

FIG. 2 is a top view showing a solar cell according to a preferred embodiment of the invention. FIG. 3 is a cross-sectional view showing the solar cell taken along a line 3-3 of FIG. 2. As shown in FIGS. 2 and 3, the solar cell with high photon utilization according to this embodiment of the invention includes a substrate 10, a transparent conductive oxide layer 20, an anti-reflection coating (ARC) layer 30 and at least one main charge collecting line 40. In this embodiment, the solar cell has two main charge collecting lines 40.

The substrate 10 has a front side 10F and a back side 10B. The substrate 10 has a first-type semiconductor layer (e.g., P-type or N-type semiconductor layer) 12 close to the back side 10B, and a second-type semiconductor layer (e.g., N-type or P-type semiconductor layer) 14 close to the front side 10F. The substrate 10 is, for example, a silicon substrate.

The transparent conductive oxide layer 20 is formed on the front side 10F. The material of the transparent conductive oxide layer 20 is selected from the group consisting of zinc oxide (ZnO), tin dioxide (SnO₂) or titanium dioxide (TiO₂), and may have textures formed by the surface roughening processes. The ARC layer 30 is formed on the transparent conductive oxide layer 20. In this embodiment, the ARC layer 30 is made of silicon nitride or titanium oxide.

The main charge collecting line 40 penetrates through the ARC layer 30 and projects from the ARC layer 30, and is electrically connected to the transparent conductive oxide layer 20. Because the main charge collecting line 40 has been electrically connected to the transparent conductive oxide layer 20, no secondary charge collecting line 50 has to be formed on the ARC layer 30 by way of screen printing while the charge collecting effect can be achieved. However, the secondary charge collecting lines 50 may also be formed on the ARC layer 30 by way of the screen printing. In this case, the solar cell may further include a plurality of secondary charge collecting lines 50, which penetrates through the ARC layer 30, projects from the ARC layer 30 and is electrically connected to the main charge collecting line 40.

The transparent conductive oxide layer 20 may be directly electrically connected to the substrate 10, and the main charge collecting line 40 may be directly electrically connected to the transparent conductive oxide layer 20. Thus, no main charge collecting line and no secondary charge collecting line have to be formed on the transparent conductive oxide layer 20 by way of the screen printing, or only a few secondary charge collecting lines have to be formed by way of the screen printing, while the charge collecting effect still can be achieved.

In addition, the solar cell of this invention may further include a back side electrode layer 60 and a back side metal layer 70, both of which are disposed on the back side 10B of the substrate 10.

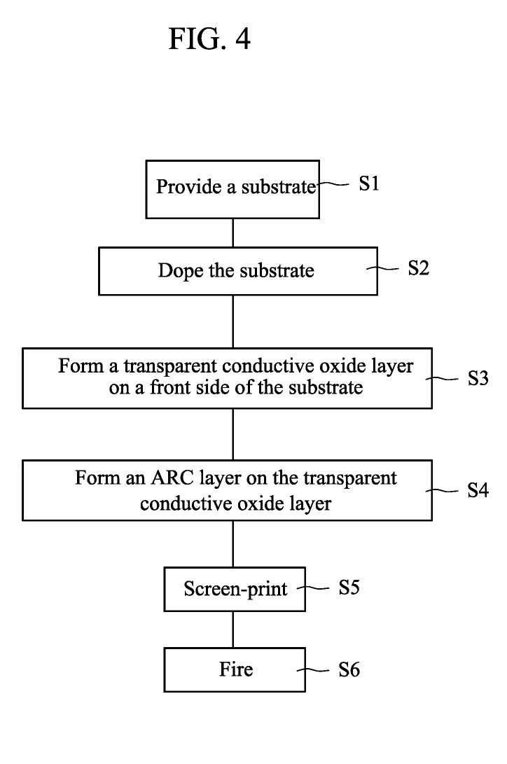

FIG. 4 is a flow chart showing a method of manufacturing the solar cell according to the invention. Referring to FIGS. 4 and 3, the method of manufacturing the solar cell includes the following steps.

In step S1, the substrate 10 having the front side 10F and the back side 10B is provided.

In step S2, the substrate 10 is doped such that the substrate 10 has the first-type semiconductor layer 12 close to the back side 10B and the second-type semiconductor layer 14 close to the front side 10F.

In step S3, the transparent conductive oxide layer 20 is formed on the front side 10F of the substrate 10. In order to enhance the diffusing effect, the transparent conductive oxide layer 20 may be patterned to form the textures by way of wet etching.

In step S4, the ARC layer 30 is formed on the transparent conductive oxide layer 20.

In step S5, the at least one main charge collecting line 40 and the secondary charge collecting lines 50, which are electrically connected to the main charge collecting line 40, are formed on the ARC layer 30 by way of the screen printing. In addition, the back side electrode layer 60 and the back side metal layer 70 may also be formed on the back side 10B of the substrate 10 by way of the screen printing. It is to be noted that the secondary charge collecting lines 50 may also be omitted

In step S6, the main charge collecting line 40 and the secondary charge collecting lines 50 are fired such that the main charge collecting line 40 and the secondary charge collecting lines 50 penetrate through the ARC layer 30 and are thus electrically connected to the transparent conductive oxide layer 20.

The solar cell according to the invention may have the following advantages. Because the transparent conductive oxide layer and the ARC layer may diffuse the light rays multiple times, the diffusing effect is enhanced and the light ray availability may be greatly enhanced. In addition, because the density of the secondary charge collecting line may be reduced, or even no secondary charge collecting line has to be formed, the light shielding ratio may be effectively reduced so that the high photon utilization is obtained.

While the invention has been described by way of examples and in terms of preferred embodiments, it is to be understood that the invention is not limited thereto. To the contrary, it is intended to cover various modifications. Therefore, the scope of the appended claims should be accorded the broadest interpretation so as to encompass all such modifications.

What is claimed is:

1. A solar cell with high photon utilization, the solar cell comprising:
a substrate having a front side and a back side, the substrate having a first-type semiconductor layer close to the back side, and a second-type semiconductor layer close to the front side;
a transparent conductive oxide layer formed on the front side;
an anti-reflection coating (ARC) layer formed on the transparent conductive oxide layer; and
at least one main charge collecting line, which penetrates through the ARC layer, projects from the ARC layer and is electrically connected to the transparent conductive oxide layer.

2. The solar cell according to claim 1, further comprising:
a plurality of secondary charge collecting lines, which penetrates through the ARC layer, projects from the ARC layer, and is electrically connected to the main charge collecting line.

3. The solar cell according to claim 1, wherein the ARC layer is composed of silicon nitride or titanium oxide.

4. The solar cell according to claim 1, wherein a material of the transparent conductive oxide layer is selected from the group consisting of zinc oxide (ZnO), tin dioxide (SnO₂) or titanium dioxide (TiO₂).

5. The solar cell according to claim 1, wherein the transparent conductive oxide layer has textures.

6. The solar cell according to claim 1, wherein the substrate is a silicon substrate.

7. The solar cell according to claim 1, further comprising a back side electrode layer and a back side metal layer, both of which are disposed on the back side of the substrate.

8. The solar cell according to claim 1, wherein the first-type semiconductor layer is an N-type semiconductor layer, and the second-type semiconductor layer is a P-type semiconductor layer.

9. The solar cell according to claim 1, wherein the first-type semiconductor layer is a P-type semiconductor layer, and the second-type semiconductor layer is an N-type semiconductor layer.

10. A method of manufacturing a solar cell, the method comprising the steps of:
providing a substrate having a front side and a back side;
doping the substrate such that the substrate has a first-type semiconductor layer close to the back side and a second-type semiconductor layer close to the front side;
forming a transparent conductive oxide layer on the front side of the substrate;
forming an anti-reflection coating (ARC) layer on the transparent conductive oxide layer;
forming at least one main charge collecting line on the ARC layer; and
firing the at least one main charge collecting line such that the at least one main charge collecting line penetrates through the ARC layer and is electrically connected to the transparent conductive oxide layer.

11. The method according to claim 10, further comprising the steps of:
forming a plurality of secondary charge collecting lines on the ARC layer, wherein the secondary charge collecting lines are electrically connected to the main charge collecting line; and
firing the secondary charge collecting lines such that the secondary charge collecting lines penetrate through the ARC layer and are electrically connected to the transparent conductive oxide layer.

12. The method according to claim 10, further comprising, before the firing step, the step of:
forming a back side electrode layer and a back side metal layer on the back side of the substrate.

13. The method according to claim 10, further comprising the step of forming textures on the transparent conductive oxide layer.

14. The method according to claim 13, wherein the textures are formed by wet etching.
